(19) United States
(12) Patent Application Publication
(10) Pub. No.: US 2012/0249118 A1
(43) Pub. Date: Oct. 4, 2012

(54) CABLE IDENTIFICATION DEVICE

(76) Inventor: KENT HADDON, IDAHO FALLS, ID (US)

(21) Appl. No.: 13/075,479

(22) Filed: Mar. 30, 2011

(51) Int. Cl. G01R 19/00

(52) U.S. Cl. 324/66

(57) ABSTRACT

Presented is a device and method for identifying a cable in a group of cables, where a transmitting inductive coupler is placed on one end of the cable and a receiving inductive coupler is used to identify the cable from among several cables. The inductive couplers are of a novel construction using split rings and copper windings around each half of the split rings. A meter is used to measure how much signal is on each of the cables tested, and a comparison of the readings indicates which cable is the same cable to which the transmitting inductive coupler is attached.

### TECHNICAL FIELD

The presently disclosed and claimed inventive concept generally relates to an apparatus for detection of electrical cables, and more particularly to identification of one cable in a group of otherwise indistinguishable cables.

### BACKGROUND

In 1882, Thomas Edison developed the first street light system in New York City. Since that time, utilities have had the problem of identifying one cable from another. Under ideal conditions cables would always be marked correctly as to the correct phase and each end of the cable would be identified. Unfortunately that is not always the case.

Since most cables are energized and cannot be taken out of service, the need for a product that could perform on an energized cable as well as a de-energized cable has been a major problem. The need for a product that can either identify the correct cable or tell the operator that it cannot identify the correct cable has been needed for a long time. Cutting into an energized cable, or removing a cable from service that should not be removed, can create major safety problems.

One of the methods now on the market which attempts to accomplish this job is the direct current (DC) impulse method. The DC impulse method can identify an energized high voltage cable as the one that is de-energized and grounded. The problem with this is that utility workers have been killed when they cut into an energized cable that they thought was grounded, because the DC impulse method does not always work.

Identification of cables using radio signals has also been tried. Radio signals that are connected directly to a conductor have two major problems. A conductor in the moving magnetic field will have some signal induced in it. When a signal is placed on a conductor in the conductive mode or direct connection the signal will travel into all conductors that are electrically tied together at an equal level. Since the signal is at an equal level in all conductors, identifying the conductor that the signal is placed on by direct connection cannot be done.

### SUMMARY OF THE DISCLOSURE

The disclosed technology is a device and method for identifying a selected conductor from among a group of conductors, which may be energized conductors or non-energized. The device of the disclosed technology includes a transmitting split ring inductive coupler (TSRIC) which is configured for placement on a first selected conductor. The device also includes a second inductive coupler, called the receiving split ring inductive coupler (RSRIC), typically, the TSRIC would be placed on part of a conductor by use of the split ring feature of the coupler. The split ring forms a 360° ring, which is split in two places and hinged on one of those places. When the split ring conductor is opened, it may be placed so that it surrounds a coupler in a 360° manner.

When an inductive coupler of the invention is used to identify a cable, the conductor must be grounded at both ends, and the method of the technology includes verifying that the conductors are grounded. The ground can be through a load of some type, but the signal needs to see a ground at both ends of the conductor. If the conductor is not grounded at both ends, signal cannot be applied to the conductor using an inductive coupler of the invention. One split ring inductive coupler of the invention is a transmitter, and one is a receiver. Experience has shown that when applied to one end of a conductor that is grouped with other conductors, the signal from the inductive coupler transmitter of the invention does not go out on the other conductors at an equal level. The signal will divide down at an equal amount if the signal sees another conductor before it sees the ground. If the signal is able to see five conductors at a junction tie point of some type, like the common junction of conductors inside a transformer enclosure, the signal would divide into a 20% level on each of the five cables.

The invention allows the identification of one cable from another, in or out of a trench, live or dead. The invention consists of three items: one receiver or meter, and two inductive couplers. One inductive coupler is the transmitting split ring inductive coupler (TSRIC), and another is the receiving split ring inductive coupler (RSRIC).

When the transmitting split ring inductive coupler is installed around a conductor, a tracing tone verifies that there are two ground rods on that cable. A receiving split ring inductive coupler can be used to trace the route of that cable under test, and identify the conductor in question from among a group of conductors.

Both inductive couplers may have a hot stick ring on one side that allows the jaws to be opened and closed using a hot stick. A ¼-20 threaded insert is at the back end so a threaded extension rod can be installed. With a cord tied to the hot stick ring, the opening and closing of the coupler jaws can be remote if a hot stick is not available.

Before starting a conductor identification, all batteries on the devices are first checked. The battery test procedure starts for the transmitting split ring inductive coupler by turning the transmitting split ring inductive coupler on. It has a battery test function, such as a red LED that will blink every 3 or 4 seconds if the battery is good. If the LED or other indicator fails to blink, the battery should be replaced.

The signal receiver batteries may be checked by turning on the signal receiver with the on/off switch. After the signal receiver has completed its start-up self test, a receiver battery verification is initiated. For instance, the word GAIN or a similar message will appear on the display. A battery test switch is present and may be pressed. The battery voltage will be provided on the display. A battery symbol may also appear on the display to indicate battery charge. If the battery voltage drops below the proper level for operation, the battery symbol will indicate so, such as by a flashing light. The battery voltage is also displayed for a few seconds during the start-up self test. To replace the batteries, the battery cover at the back end of the handle is removed, and the battery connector is loosened to remove the battery holder.

In use, the receiving split ring inductive coupler is used to identify the conductor on which the transmitting split ring inductive coupler is placed. The point of identification is at a position away from the transmitting split ring inductive coupler, and each of the conductors at that position are sequentially surrounded by the receiving split ring inductive coupler, and their signal strength is noted.

The signal receiver is operatively connected to RSRIC, and is provided with a measuring means for measuring a signal in the conductor as sensed by the RSRIC. The operative connection to the signal receiver may be by a conductor, or wirelessly. The sensed signal is sent from the TSRIC. By comparing the signals on each of the groups of couplers in question, which of the conductors is the conductor on which the TSRIC is placed may be ascertained.

An important feature of the device includes the specific manner in which the two inductive couplers are prepared. Both inductive couplers form a ring which surrounds a conductor in a 360° manner. Each of the rings is split in two placed, and hinged at one of those splits. Each of the rings is wrapped with copper wire in a special winding pattern. Each of the conductors are made of magnetic core material, such as grain oriented silicone steel. Each half of each inductive coupler is wound with copper wire with each winding turn uniformly spaced apart from neighboring turns, with the winding covering the entirety of the two half circles of magnetic core material, and with the winding configured to be energized when placed over a conductor.

A floating rocker hinge can be utilized to connect the two half circles of the magnetic core material of the two inductive couplers.

The disclosed technology also is a method for identifying a selective conductor from a group of conductors. The method includes the step of exposing a first selected conductor and attaching a transmitting split ring inductive coupler to the first selected conductor. By attaching what is meant is placing the inductive coupler around the conductor so that it is basically surrounded by 360° by the inductive coupler. The next step is verifying that the group of conductors being tested are grounded at each end. The next step is to connecting a signal receiver to a receiving split ring inductive coupler. The next step is sequentially attaching the receiving split ring inductive coupler to each conductor in a group of energized conductors located a distance away from the position of the transmitting TSRIC. The next step is obtaining a reading on the signal receiver which is received by the RSRIC for each of the conductors in the group, and comparing those readings. By comparing the readings, it may be determined which of the conductors tested is the same conductor as the one on which the TSRIC is placed.

Connecting the signal receiver to the RSRIC can be by a direct wire connection or can be a wireless electronic connection.

The method can further include the step of preparing the TSRIC and the RSRIC by joining two semicircular sections at a hinge, with each semicircular connection being made of magnetic core material. This step can further include winding each half of each inductive coupler with copper wire in a spiral winding, with each turn of the winding uniformly spaced apart from neighboring turns of the winding, with the windings covering the entirety of the two half circles of magnetic core material which make up each inductive coupler. The floating rocking hinge arrangement can be utilized to join the two semicircles which make up each inductive coupler.

The purpose of the Abstract is to enable the public, and especially the scientists, engineers, and practitioners in the art who are not familiar with patent or legal terms or phraseology, to determine quickly from a cursory inspection, the nature and essence of the technical disclosure of the application. The Abstract is neither intended to define the inventive concept(s) of the application, which is measured by the claims, nor is it intended to be limiting as to the scope of the inventive concept(s) in any way.

Still other features and advantages of the presently disclosed and claimed inventive concept(s) will become readily apparent to those skilled in this art from the following detailed description describing preferred embodiments of the inventive concept(s), simply by way of illustration of the best mode contemplated by carrying out the inventive concept(s). As will be realized, the inventive concept(s) is capable of modification in various obvious respects all without departing from the inventive concept(s). Accordingly, the drawings and description of the preferred embodiments are to be regarded as illustrative in nature, and not as restrictive in nature.

### BRIEF DESCRIPTION OF THE DRAWINGS

FIG. 1 shows five houses connected to a junction box, with one conductor being identified at the junction box.

FIG. 2 shows an inductive coupler of the invention.

FIG. 3 shows a signal being split in half at a junction

FIG. 4 shows an inductive coupler at a meter riser at a house.

FIG. 5 is a bundle of telephone cables with an inductive coupler attached.

FIG. 6 illustrates the placement of inductive couplers relative to grounds.

FIG. 7 shows use of the device with a jacketed primary in a junction box.

FIG. 8 shows the winding of an inductive coupler.

### DETAILED DESCRIPTION OF THE EXEMPLARY EMBODIMENTS

While the presently disclosed inventive concept(s) is susceptible of various modifications and alternative constructions, certain illustrated embodiments thereof have been shown in the drawings and will be described below in detail. It should be understood, however, that there is no intention to limit the inventive concept(s) to the specific form disclosed, but, on the contrary, the presently disclosed and claimed inventive concept(s) is to cover all modifications, alternative constructions, and equivalents falling within the spirit and scope of the inventive concept(s) as defined in the claims.

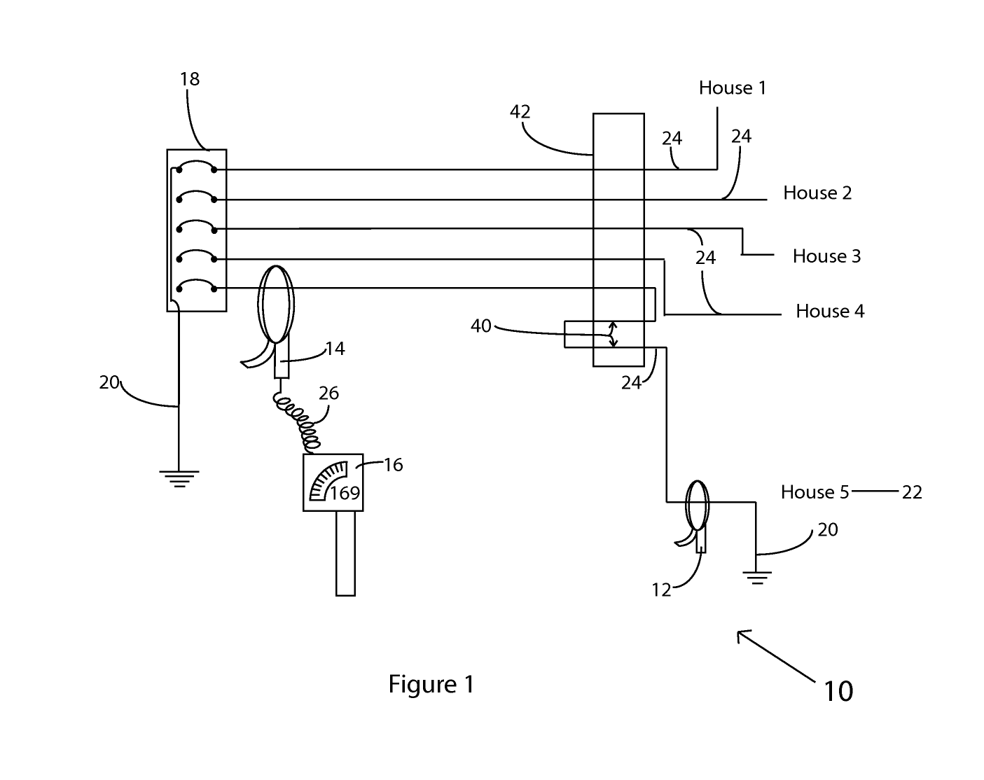

Contractors are paid by the amount of cable being trenched. Often loops of cable are found when a cable run is exposed, with some cables laid in the trench back and forth in a longs “S” pattern as shown in by the S loop in trench 40 in FIG. 1. This can also happen because it is easier to bury the loop of extra cable length than to cut out and splice the cable.

This loop of cable becomes a problem when the cables are identified using the DC impulse method. In the DC impulse method, two cables are left energized and the target cable is de-energized and isolated. At the far end, the target conductor is grounded to the neutral. An impulse generator producing a DC pulse is then connected to the target conductor and neutral. The DC pulse travels down the target conductor and then splits into equal amounts on the three neutrals and comes back to the neutral connection of the impulse generator. On the target conductor, the full impulse current is much higher than the current coming back on the neutral. By placing a split ring current transformer over each conductor feeding a zero center signal receiver, the signal receiver will trip one direction on the target conductor and the reverse direction on the other two cables because it only can measure the return current going the opposite direction.

The problem when using the DC impulse method occurs when a loop 40 is found in a trench 42 of exposed cables, as shown in FIG. 1. Figure one shows a trench 42 with what appears to be 7 cables exposed. As figure one indicates, when you open a trench and see three cables, it could be the same cable instead of the three cables in a three phase circuit. Because the direction of the zero center signal receiver providing the correct direction on one cable and the reverse direction on the other two, the operator targets the one cable as his target when, and he assumes it is dead and grounded when it is energized with high voltage. The detector of the disclosed technology, by contrast, would receive an equal signal on each cable and prevent the operator from finding the higher target signal.

FIG. 1 shows the cable identifier device 10 of the disclosed technology, with transmitting split ring inductive coupler 12 (TSRIC), receiving split ring inductive coupler 14 (RSRIC), and signal receiver 16. Conductors 24 extend from several houses 22 to illustrate one scenario for use of the cable identifier device 10. To use the device 10, the conductor 24 from house 5 is grounded at 20. The junction box 18 also has a ground 20. The TSRIC 12 is placed around the selected conductor 24, and energized. The RSRIC 14 is placed on each of the conductors 24 in sequence, at a point near the junction box 18, and the signal on each conductor is detected at the signal receiver 16. By comparing the signal at each conductor 24, the one which corresponds to the house 5 can be identified. In FIG. 1, the RSRIC 14 is connected to the signal receiver 16 by a cable 26, but the connection could also be made wirelessly.

With the TSRIC 12 connected to the utility service riser at house #5 all of the signal would be on the two hot legs and the neutral going from the utility service riser (not shown) to the junction box 18 at the transformer. At the junction box 18, the signal would divide down with 20% being on each of house #1, 2, 3, and 4, and the ground wire going to the neutral bus at the base of the junction box which is attached to a ground rod 20. Each of the above houses would have a ground rod at the base of the respective utility service riser at each house. All of the signal will be on the conductor 24 leading to house #5. This allows the operator to trace the conductor 24 from house #5 to the junction box 18 and then identify the neutral and the two hot legs by using the RSPIC 14 to measure the signal level on each conductor at the terminal block. As an example, the signal on the house 5 conductor could be 500 (units) while the signal on house 1 could be 100, house 2 could be 100, house 3 could be 100, and house 4 could be 100 units.

The conductor being identified shows a higher signal than other conductors present, letting the operator know if the conductor selected is the cable on which the transmitting coupler is installed. If signals at the different conductors are not sufficiently different, the operator will know there is a problem in the test set up, or there are conditions of the cables being tested that are not known, and thus and no identification is available. FIG. 1 shows how signal from the TSRIC will travel at full strength to each ground rod if it encounters the ground rod before it locates another conductor. If it encounters another conductor before it encounters the ground rod, the signal will divide down.

Split ring transformers have been used for years in measuring electrical current like in the watt hour meter at a house. If such prior art couplers are in a permanent position they can be calibrated for accuracy. If their position changes, their accuracy would not be correct until they were recalibrated for their new position in relation to the conductor being measured. When trying to identify one conductor from many, the major signal on the conductor coming to the junction block and then the reduced signal on the other four conductors, problems arose. Using prior art testers, the signal was not consistent in the receiving inductive coupler. This is due to the manner in which prior art inductive couplers are made. The typical prior art inductive coupler is a two piece clamp with semicircular jaws hinged together at one end, which come together to form a circle around a conductor. The jaw portions are typically made of magnetic core material, such as grain oriented silicone steel Around one of the jaws a coil of conductive copper wire is typically wound tightly, with the wires touching each other and forming a coil about 1-2 inches wide.

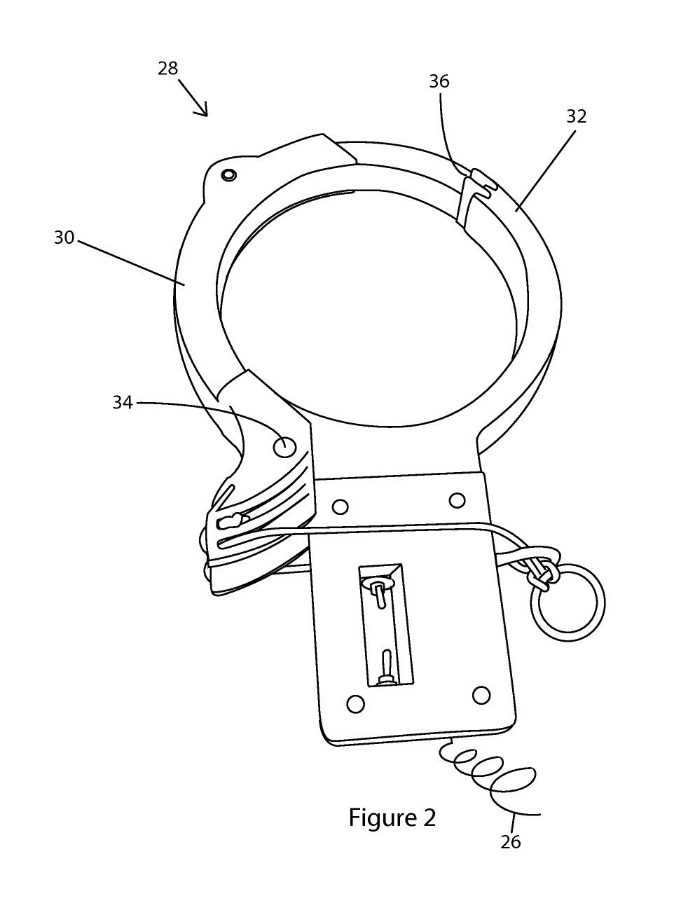

Part of the success of the present invention is the design of the inductive couplers of the device, and how they are wired. An inductive coupler of the invention is shown in FIG. 2. An inductive coupler 28 of the invention is typically made of grain oriented silicon steel, and includes a first side 30 of the loop and a second side 32 of the loop. The transmitting split ring inductive coupler has the same type of coil winding as does the receiving split inductive coupler. Having equal coil winding patterns on both the transmitting split ring inductive coupler loop and the receiving split ring inductive coupler, the signal level on the conductor as sensed by the signal receiver 16 remains unaffected by the positioning of the conductor 24 within the loop of the RSPIC coupler 14 or the TSRIC 12. This winding of the receiving inductive coupler and the transmitting inductive coupler is critical to being able to duplicate signal levels that can be used in the comparison needed for identification.

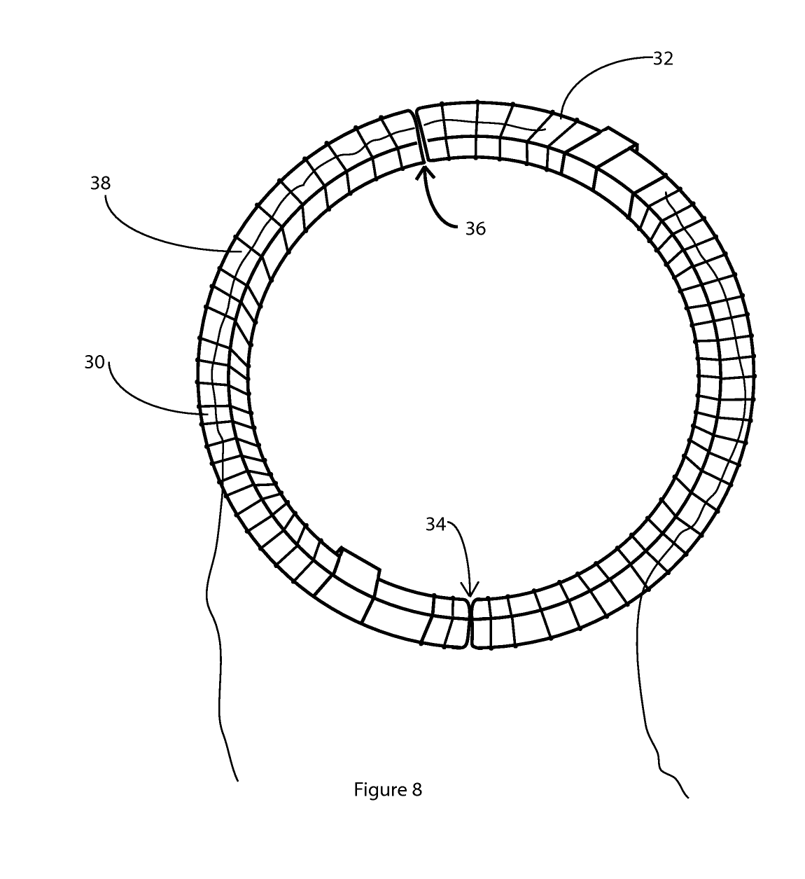

The two sides form a basically circular loop 4 or more inches in diameter, as an example, which is placed around a conductor. Different applications may dictate a different diameter of the loop of the inductive couplers, but a loop of 4 inches in diameter has proven to be useful in many applications. A wire conductor such as 26 gauge insulated copper is wound around each of the jaws, with the coil being evenly spread over the jaw, with an even spacing between each conductor. FIG. 8 shows this style of winding, with each winding 38 of the coil being placed approximately 0.1 inches from the neighboring winds on either side. With this configuration, the signal received at the receiving inductive coupler is consistent at the same signal strength regardless of where the conductor being tested is positioned inside the receiving coupler loop. The structure of the device also reduces the inter-electrode capacitance loss of signal between windings when the coil wind is spaced equally around the entire loop. After winding, the wire forming the coil around each arm of the loop is covered with epoxy to hold it in place and to insulate it. The two sides are joined at a hinge 34, and the two sides 30 and 32 touch at their tips 36. The metal core of each loop of the inductive couplers is preferably approximately ¼ inches thick.

As shown in FIG. 2, inductive couplers of the disclosed technology are wound evenly over the entire core, which eliminates the position problem except for the area where the split cores came together. The wind must be close enough to the core contact points to overcome the discontinuity of the core contact point and the core itself. An amplitude change can be found near the two contact points if this has not been addressed by the coil position where the two cores meet.

Since the wind is also evenly spaced, it reduces the capacitive reactance between each wire loop that is present in a bundled coil as is typical in the prior art. By the winding pattern of the disclosed technology, the efficiency of signal loss from cancellation is greatly improved. Since energy loss is improved, less power is required to provide the same signal level as that of a bundle wrap winding.

Use of a “hot stick” or what is called a “shotgun stick” allows the TSRIC and RSRIC to be placed on bare bus circuits even when they are energized. All of the other couplers being produced have the transmitter signal driven into the core winding from a transmitter that is connected to each other with a cord. This type of design has a danger in voltage arcing back into the transmitter and creating a problem for the operator is great, and eliminated by the disclosed technology which used a wireless TSRIC powered by a battery. Further, the TSRIC has a floating rocker mechanism that allows positive contact points where the core comes together.

One preferred embodiment utilizes a wireless RSRIC that can be placed on different conductors. By the use of the wireless RSRIC and the wireless TSRIC, a reading can be taken and stored. After moving the RSRIC to different conductors and taking each reading, the data can be retrieved and all readings compared. This could be bare bus conductors in a sub-station, or in the other scenarios illustrated in the figures.

The disclosed technology can be used on energized cable, un-energized cables, high voltage cables, low voltage cables, in the trench, out of the trench, transformer to transformer, transformer to house or vault to vault and with a utility hot stick, it can be done from a safe distance if required.

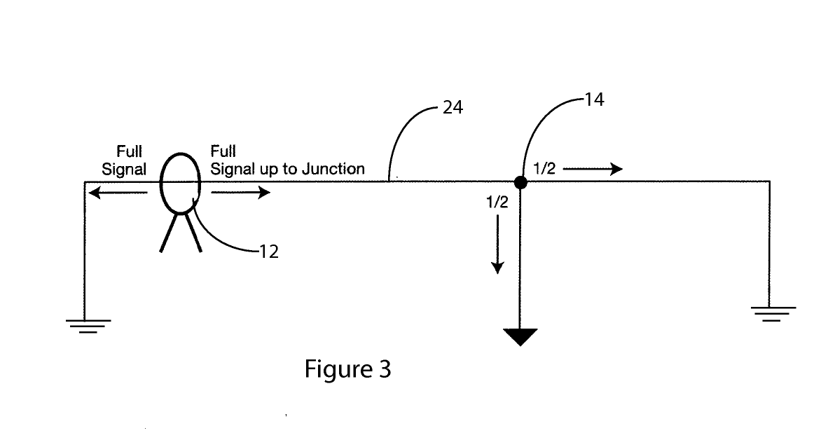

FIG. 3 shows how the signal from the TSRIC divides at junctions in the conductors. The types of cables that may be tested with this receiver includes those listed below and those shown in the figures. The methods used to identify one cable from another is slightly different for shielded and unshielded cables. As a result, this discussion is divided into three parts.
Insulated Cables.—Secondary and street light cables.
Low voltage Shielded Cables—Cable T.V. and telephone.
Jacketed High Voltage Primary Cables

Unlike other methods of applying signal which can place the same amount of signal on every circuit that is electrically connected, the transmitting coupler signal will go to the first ground it can find on both sides of the coupler. The signal will divide down and be much less on the other conductors that are connected to the same ground. The major portion of the signal will be on the conductor the TSRIC is clipped around, between the grounds at both ends.

If the signal finds a wire connection of two or more conductors at some junction point before it finds the ground, the signal will divide down with much smaller signal being on each conductor. See FIG. 3.

When installing the wireless inductive coupler to a cable, the cable must be inside the coupler ring with the couplet; closed and the cable must be grounded at both ends. The ground can be through a load on energized cables. This also applies to the conductor of a de-energized primary cable. The neutral and conductor must be grounded at both ends. If the conductor is not grounded at both ends, the TSRIC will not apply a signal to the conductor.

When making a cable identification, each cable is measured in sequence. The gain control on the RSRIC is adjusted for a mid-scale reading on the display for each cable. Once the gain control is set for a mid-scale reading on the cable that has the most signal, all of the other cables under test will have much less signal at that gain setting. The cable which yields the highest reading will be the cable to which the TSRIC is attached.

### Secondary—Street Light Cables.

Place the wireless transmitting coupler around the utility service riser conduit, or a single conductor, is one scenario of operation for the device. The coupler is turned on, with the low-high power switch on low. High power can be used but in most cases it is not required and low power will reduce the chance of inducing signal into other circuits.

From where the transmitting coupler is installed, signal will travel in both directions to its respective grounds. This will allow the receiving coupler to be used at any access point between the two grounds.

The receiver is turned on and the receiving inductive coupler is installed using a provided phone jack. When ready, readings may be taken using the receiver. For instance, a number may be displayed in the display of the receiver, typically being a number from 0 to 100. This number is the percentage number of where the sensitivity control is set. A reading of 25 would be 25% of the sensitivity control use. This will allow the operator to identify the different signal levels on each cable under test.

The receiving coupler is then placed around each cable of those to be identified, one at a time. The cable with the highest signal reading on the display will be the cable to which the wireless transmitter is attached. All of the other cables could have signal on them, but the signal level will be much lower than the one to which the transmitting coupler is attached.

With the receiving coupler around the first cable being tested, the sensitivity control is adjusted for a mid-scale reading, such as on a bar graph. If the second cable has a lower or equal reading, the sensitivity control is left in position, and the receiving coupler is moved to the next cable. If the reading on the second cable is higher than the first cable, the sensitivity control is adjusted down for the mid-scale bar-graph reading. When the cable has been found that has the mid-scale reading and all other cables under test have a much lower reading or no signal reading at all at that gain setting, the cable with the highest reading is the cable to which the wireless transmitting coupler is clipped. A numerical signal level may be positioned in the lower center of the display in addition to the bar-graph, or in place of the bar graph. This numerical number is tied to the bar graph and will provide the highest numerical reading on the correct cable.

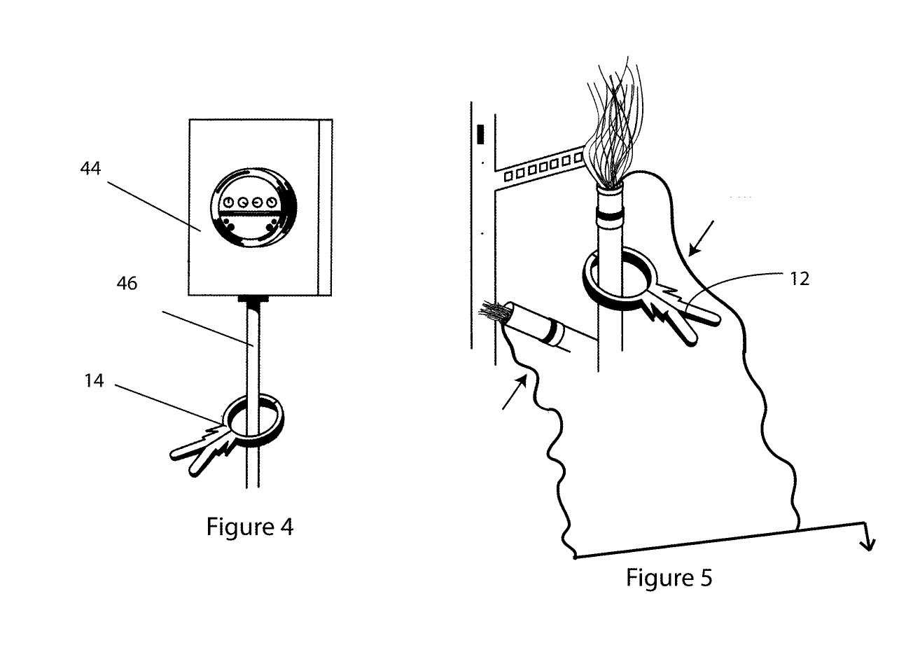

FIG. 4 shows the TSRIC attached to a meter riser 46 connected to a meter 44, such as might be found at a house. In this position the coupler 12would be around both hot legs and the neutral. At the transformer, the RSRIC will identify both hot legs and the neutral going to that utility service riser 46.

FIG. 5 shows the TSRIC attached to a bundle of sheathed wires such as CATV or telephone wires. These cables have a metallic sheath around the outside of the internal conductors. Since the sheath is also a magnetic shield to radio waves, the TSRIC must be placed around the outer jacket of the CATZ or telephone cable that includes the sheath. The RSRIC must also be placed around the outer jacket of the entire cable, or on individual conductors at both ends.

### Jacketed Primary

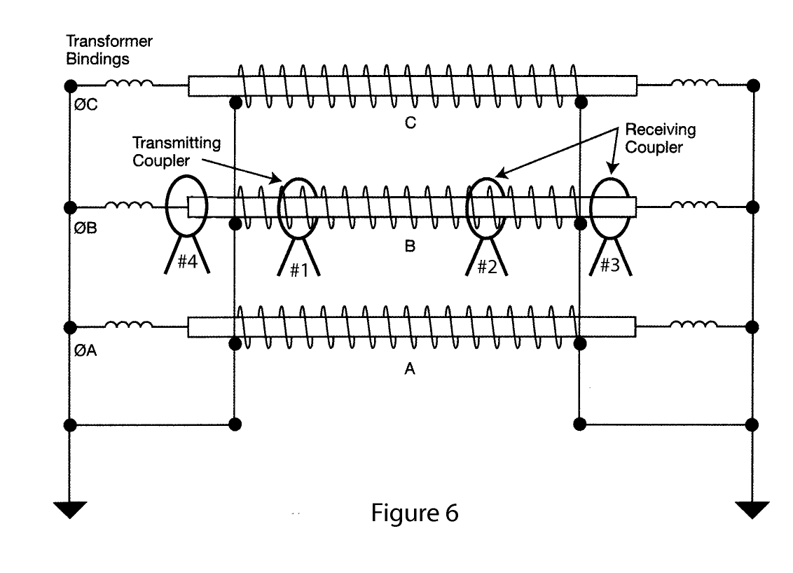

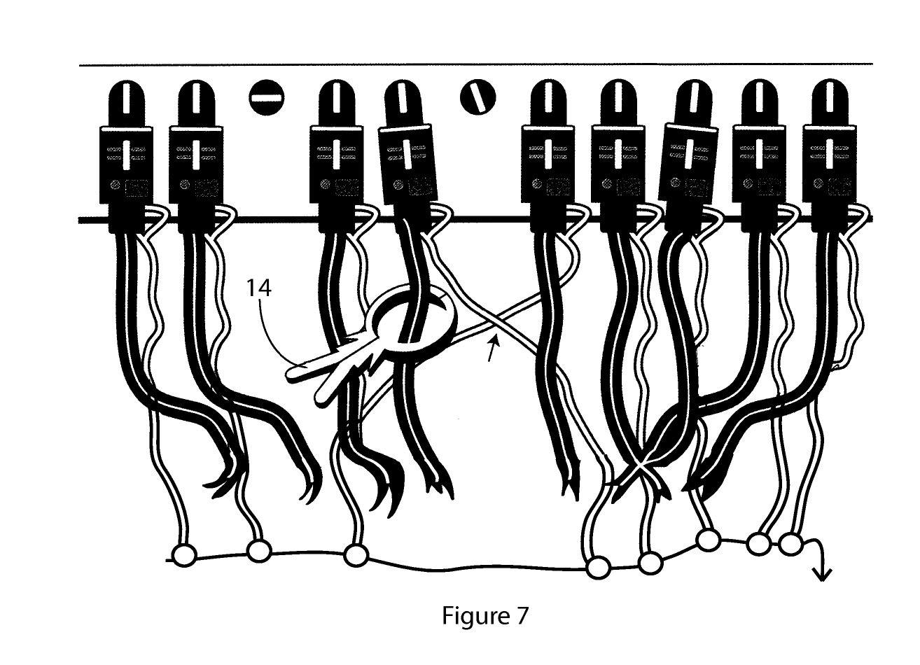

FIG. 6 shows use of the device of the invention on a jacketed primary. The concentric neutral has a ground rod at both ends and a semi-conductive jacket around the neutral. Since the neutral is isolated from the soil, the TSRIC can be placed around the outer jacket and the signal will transmit in both directions to the two ground rods. FIG. 6 shows the coupler positions for measuring this type of conductor. The TSRIC should be placed at position #1, and the RSRIC is placed at position #2. Position 3 could give incorrect readings. If the TSRIC is placed at position #4, placing the RSRIC in position # 3 will receive the strongest signal because of neutral shielding. NOTE: If the transmitting coupler is placed around the entire cable, the receiving coupler must be placed around the entire cable. If the transmitting coupler is placed around the conductor only, the receiving coupler must be placed around the conductor only for all cables under test.

Shown in FIG. 7 are a number of jacketed primary conductors. There are several conditions that could limit the ability to make a positive cable identification in the arrangement shown in FIG. 7.

First reason: Neutral pigtails touching other pigtails between the neutral break out and the ground bus wire at the base of a transformer. The signal will divide where it touches another conductor before it finds the ground rod. On the cable the TSRIC is on, the pigtail should go to the ground bus at the base of the enclosure or ground rod without touching other pigtails.

Second reason: A non-jacketed section of primary spliced into a jacketed primary. Even though the TSRIC is around a jacketed cable, at the point where the bare neutral of the non-jacketed cable is touching the soil may look like a ground rod to the signal. All the operator may see is a jacketed cable at both ends and may be unaware of the non-jacketed section. The readings taken will not be what the operator is looking for in proof positive identification.

Because of the two mentioned and many more problems that could exist, all cables should be considered energized unless they have been physically grounded and all cables are spiked before they are cut.

While certain exemplary embodiments are shown in the Figures and described in this disclosure, it is to be distinctly understood that the presently disclosed inventive concept(s) is not limited thereto but may be variously embodied to practice within the scope of the following claims. From the foregoing description, it will be apparent that various changes may be made without departing from the spirit and scope of the disclosure as defined by the following claims.

The purpose of the Abstract is to enable the public, and especially the scientists, engineers, and practitioners in the art who are not familiar with patent or legal terms or phraseology, to determine quickly from a cursory inspection, the nature and essence of the technical disclosure of the application. The Abstract is neither intended to define the inventive concept(s) of the application, which is measured by the claims, nor is it intended to be limiting as to the scope of the inventive concept(s) in any way.

What is claimed is:

1. A device for identifying a selected conductor from a group of energized conductors, comprising:
a transmitting split ring inductive coupler (TSRIC) for placement on a first selected conductor;
a receiving split ring inductive coupler (RSRIC) for sequential placement on one of a plurality of conductors at a position away from said transmitting split ring inductive coupler, to identify one of said plurality of conductors as being a second end of said first selected conductor; and
a signal receiver operatively connected to said RSRIC, for measuring a signal in each of the conductors, received from the TSRIC, with a comparison of the measured signals indicating which of the energized conductors is the second end of the selected conductor.

2. The device of claim 1, in which said RSRIC is connected to said signal receiver by a direct connection.

3. The device of claim 1, in which said RSRIC is connected to said signal receiver by a wireless electrical connection.

4. The device of claim 1 in which said TSRIC and RSRIC are each comprised of two half circles of magnetic core material, joined at one end by a hinge connection, and wound with copper wire in a spiral winding with each winding turn uniformly spaced apart from neighboring turns, with said winding covering the entirety of said two half circles of magnetic core material, with winding configured to be energized.

5. The device of claim 1 in which said TSRIC is comprised of two half circles of magnetic core material joined in a floating rocker hinge arrangement.

6. The device of claim 1 in which said signal receiver is configured to emit a tracing tone in response to a signal received at said RSRIC from said TSRIC.

7. A method of identifying a selected conductor from a group of conductors, comprising the steps of:
exposing a first selected conductor, and attaching a transmitting split ring inductive coupler (TSRIC) to said first selected conductor;
verifying said group of conductors are not isolated;
operatively connecting a signal receiver to a receiving split ring inductive coupler (RSRIC);
sequentially attaching said receiving split ring inductive coupler (RSRIC) to each conductor in a group of energized or grounded conductors;
comparing readings on said signal receiver for each of the conductors in the group of energized or grounded conductors, and determining from the readings from each of said conductors which conductor is the same as the conductor with the TSRIC attached.

8. The method of claim 7 in which the step of operatively connecting the signal receiver to the RSRIC is by direct wire connection.

9. The method of claim 8 in which the step of operatively connecting the signal receiver to the RSRIC is by wireless electronic connection.

10. The method of claim 7 which further comprises the step of preparing the TSRIC and RSRIC by joining two half circles of magnetic core material, joining them at one end by a hinge connection, and winding each half of each half circle with copper wire in a spiral winding with each turn of said winding uniformly spaced apart from neighboring turns of said windings, with said windings covering the entirety of the said two half circles of magnetic core material.

11. The method of claim 9 in which at least one of said couplers are joined in a floating rocker hinge arrangement.

12. The method of claim 7 in which said step of connecting a signal receiver to a RSRIC further comprises the step of providing said signal receiver with a tracing tone to indicate a signal received from said TSRIC.
